(19) United States
(12) Patent Application Publication
(10) Pub. No.: US 2023/0361226 A1
(43) Pub. Date: Nov. 9, 2023

(54) Semiconductor Light Receiving Element

(71) Applicant: Nippon Telegraph and Telephone Corporation, Tokyo (JP)

(72) Inventors: Masahiro Nada, Musashino-shi, Tokyo (JP); Yasuhiko Nakanishi, Musashino-shi, Tokyo (JP); Shoko Tatsumi, Musashino-shi, Tokyo (JP)

(21) Appl. No.: 18/246,595

(22) PCT Filed: Oct. 8, 2020
(86) PCT No.: PCT/JP2020/038106

§ 371 Date: Mar. 24, 2023

(51) Int. Cl. H01L 31/0216

(52) U.S. Cl. CPC H01L 31/02164

(57) ABSTRACT

A structure for blocking light incidence to a peripheral part of an element is applied to a rear surface portion, and when optically coupled to a light receiving element, the light is made incident to a center part of the element without fail. An embodiment relates to a semiconductor light receiving element, including a semiconductor light-absorbing layer on a front surface of a semiconductor substrate, for receiving signal light from a rear surface of the semiconductor substrate, and a transmittance of an inner region of a similar shape having a same center as an operating region defined in the semiconductor light-absorbing layer on the rear surface of the semiconductor substrate is higher than that of an outside of the shape.

### TECHNICAL FIELD

The present invention relates to a high-speed and high-sensitivity semiconductor light receiving element.

### BACKGROUND ART

The semiconductor light receiving element has a role of converting an incident optical signal into an electric signal, and is widely applied to an optical receiver in optical communication, a photo mixer for a millimeter wave oscillator, and the like.

The basic structure of the semiconductor light receiving element is roughly divided into two. One is a waveguide type structure in which incident light is made incident from a direction parallel to a substrate surface, and the other is a vertical incidence type structure in which incident light is made incident from a direction perpendicular to the substrate surface. In the waveguide type structure, incident light propagates in a light absorbing layer formed by crystal growth perpendicularly to a film thickness direction, and generated photocarriers move in the film thickness direction. Therefore, since the carrier transport time can be shortened while improving the light absorption efficiency, the waveguide type structure is a structure for high speed and high sensitivity. On the other hand, the vertical incidence type structure has the advantage that the element can be easily formed and the optical coupling of the manufactured element can be easily performed.

As performance indexes required for the semiconductor light receiving element, dark current, light-receiving sensitivity, and operating band are important. When the light receiving elements of the vertical incidence type and the waveguide type are compared, generally, trade-off between the light-receiving sensitivity and the operating band is more remarkable in the vertical incidence type. This is related to an optical path length of the light propagating in the light absorbing layer and the traveling distance of the carrier. On the other hand, it is relatively difficult to reduce the dark current in the waveguide type light receiving element. In the vertical incidence type, a structure for selectively generating an electric field only on side surfaces of the element is easily adopted, and a side surface dark current which is a main component of the dark current is reduced. On the other hand, in the waveguide type, it is difficult to adopt such a structure.

FIG. 1 shows an example of a conventional vertical incidence type light receiving element. Typical examples of vertical incidence type include, for example, inversion type structures disclosed in NPL 1. In the light receiving element inversion type structure, a mesa 3 including a light absorbing layer is formed on the front surface of a substrate 1 via a contact layer 2. Further, the mesa corresponding to the uppermost contact layer 4 defines an actual operating region 5 of the light absorbing layer. In the terrace portion corresponding to the portion other than the mesa at the uppermost part, the electric field strength does not increase even if the voltage of the light receiving element is increased. Therefore, even if the applied voltage is high, the electric field on the side surfaces of the element is kept small, and the dark current on the side surfaces can be reduced.

This inversion type structure is superior in scalability because the operating area of the element can be defined by etching the uppermost mesa. Therefore, even in the case of the vertical incidence structure, high speed operation to some extent can be easily realized in the inversion type structure.

The operation of the conventional vertical incidence type light receiving element will be described with reference to FIG. 2. The light receiving element is a rear surface incidence type in which light is made incident on the light absorbing layer from the rear surface of the substrate. In the inversion type structure, even if the incident light L₁ does not impinge on the center part of the element or a part where an electric field is generated in the element, the light-receiving sensitivity of a certain degree can be observed. This is because, when light is incident on the light absorbing layer corresponding to the terrace part of the element, carriers are taken out of the element by diffusion movement of an electron/positive hole. However, the carrier which is diffused and moved has a smaller moving speed than a drift movement in which the carrier is accelerated and moved by the electric field. Therefore, when the incident light L₁ is deviated from an actual operating region 5 which is the center of the element, that is, a region where an electric field is generated, the carrier has two components of a component A which diffuses in a lateral direction and has a slow speed and a component B which drifts in the longitudinal direction and has a high speed. Therefore, the response speed is remarkably deteriorated compared with the case where the incident light L₁ is applied to the center part of the element.

In a light receiving element in which the operating region of the element is reduced for the purpose of ultra-high speed operation, such deterioration in response speed becomes an important problem. When the element diameter is reduced, the optical tolerance of the incident light and the light-receiving region becomes smaller. Normally, optical alignment is performed so that incident light is made incident on the center of the operating region, but in alignment by the non-modulated light (CW light), both the component A having the slow speed and the component B having the fast speed are detected. Thus, even if incident light is made incident while being deviated from the center of the operating region, a change of a photocurrent is small, and an accuracy of alignment cannot be improved. In the case of receiving modulated light such as several tens GHz in the subsequent actual operation, if the accuracy of alignment is poor, an influence of the component A having the slow speed remarkably appears and the response speed may deteriorate.

This is a common problem in the light receiving element having an electric field confinement structure aiming at low dark current and eventually high reliability.

As described above, in the vertical incidence type light receiving element aiming at a low dark current of the light receiving element, the operating area of the light receiving element is reduced in order to increase the speed. In this case, in the light absorbing layer of the light receiving element, the photo-carriers generated by the incidence of the signal light in the operating region and the photo-carriers generated by the incidence of the signal light in a peripheral part are mixed. In this state, when optically coupled with non-modulated light, expected light-receiving sensitivity can be obtained, but high-speed operation may be impaired due to slow response of photocarriers generated in the peripheral part. Therefore, an optimum optical coupling becomes difficult.

### CITATION LIST

### Non Patent Literature

[NPL 1] M. Nada et al., “Triple-mesa avalanche photodiode with inverted p-down structure for reliability and stability”, J. Lightwave Technol., 32, 1543 (2014)

### SUMMARY OF INVENTION

An object of the present invention is to provide a semiconductor light receiving element capable of realizing a high-speed operation by applying a structure for blocking light incidence to a peripheral part of the element to a rear surface portion and making light incident to a central part of the element without fail when optically coupled to the light receiving element.

In order to achieve such the object, an embodiment of the present invention is a semiconductor light receiving element, including a semiconductor light absorbing layer on a front surface of a semiconductor substrate, for receiving signal light from a rear surface of the semiconductor substrate, wherein a transmittance of an inside region on the rear surface of the semiconductor substrate with a similar shape having the same center as the operating region determined in the semiconductor light absorbing layer is higher than the transmittance of an outside of the shape.

### BRIEF DESCRIPTION OF DRAWINGS

FIG. 1 is a cross-sectional view showing an example of a conventional vertical incidence type light receiving element.

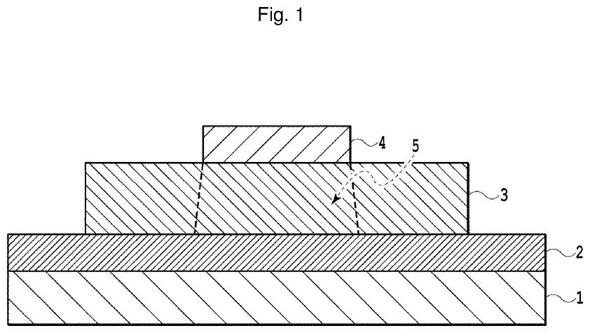

FIG. 2 is a cross-sectional view showing an operation of the conventional vertical incidence type light receiving element.

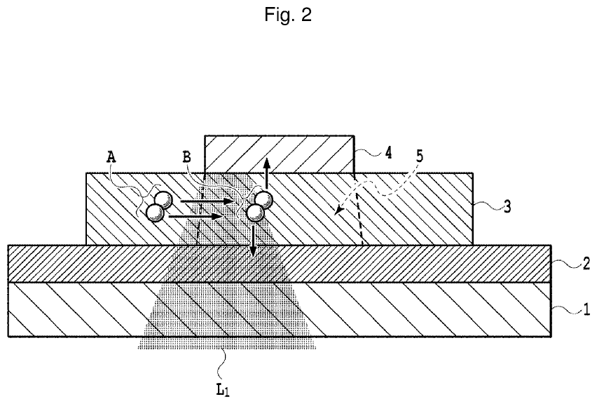

FIG. 3 is a diagram showing a construction of the light receiving element according to a first embodiment of the present invention.

FIG. 4 is a diagram showing a construction of the light receiving element according to a second embodiment of the present invention.

FIG. 5 is a diagram showing a construction of the light receiving element according to a third embodiment of the present invention.

FIG. 6 is a diagram showing a construction of the light receiving element according to a fourth embodiment of the present invention.

### DESCRIPTION OF EMBODIMENTS

The following is a detailed description of embodiments of the present invention with reference to the drawings.

### First Embodiment

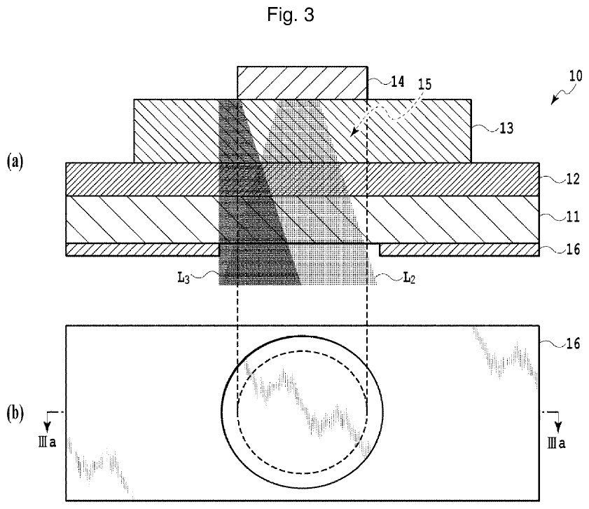

FIG. 3 shows a structure of a light receiving element according to a first embodiment of the present invention. FIG. 3 (a) is a cross-sectional view of a semiconductor light receiving element 10 of the vertical incidence type. The semiconductor light receiving element 10 has a layer structure in which a p-type InP contact layer 12, an undoped InGaAs light absorbing layer 13, and an n-type InP contact layer 14 are laminated in this order on the front surface of an InP substrate 11. The uppermost contact layer 14 is processed into the smallest mesa, and has a multi-stage mesa structure in which the outer shapes of the light absorbing layer 13 and the contact layer 12 are gradually increased in this order. The mesa of the uppermost contact layer 14 is formed in a circular shape. FIG. 3 (b) is a bottom view of the semiconductor light receiving element 10. On the rear surface of the light receiving element 10, a light shielding film 16 made of Ti is provided on an outside of a concentric circle having a same center as that of an operating region 15 defined by the contact layer 14. The InP substrate 11 is exposed inside the concentric circle.

An operating principle of the semiconductor light receiving element 10 according to the first embodiment will be described. Incident light to the light receiving element 10 is made incident from the rear surface of the substrate 11. The incident light is absorbed by the light absorbing layer 13, a photo-carrier is generated, and a current flows between the contact layers 12 and 14, thereby functioning as the light receiving element.

Here, when incident light L₂ from the rear surface is incident on the center part of the operating region 15, the incident light L2 is incident on the light shielding film 16 without being interrupted. Therefore, the photocurrent at the time of alignment indicates the maximum value. Since the incident light L₂ is made incident on the center part of the operating region 15, all generated photocarriers are subjected to the effect of an electric field generated in the operating region 15 and drift-move. Therefore, a desired high speed operation can be realized.

On the other hand, when the incident light L₃ is deviated from the center part of the operating region 15, a part of the incident light L₃ is shielded by the light shielding film 16, so that the observed photocurrent is extremely reduced. In this way, the transmittance of the light inside the concentric circle having the same center as that of the operating region 15 is higher than that of the region outside the concentric circle. Therefore, the photocurrent is maximized only when the signal light enters the center part of the operating region 15. Thus, an accuracy of an alignment can be improved even in the case of optical alignment by a non-modulated light (a CW light). Therefore, even when receiving modulated light of several tens GHz in a subsequent actual operation, since the accuracy of alignment is high, an influence of a component having a slow speed is suppressed, and high speed operation can be realized.

Next, a manufacturing method of the semiconductor light receiving element 10 of the first embodiment will be described. First, the p-type InP contact layer 12, the undoped InGaAs light absorbing layer 13, and the n-type InP light absorbing layer 14 are epitaxially grown in this order on the front surface of the semi-insulating InP substrate 11 by MOCVD. After crystal growth, photo lithography and etching are sequentially performed so that the contact layer 14 becomes the smallest mesa, and the light absorbing layer 13 and the contact layer 12 become larger in area in this order. After a necessary electrode or the like is formed on the contact layers 12 and 14, the rear surface of the light receiving element 10, that is, the rear surface of the substrate 11 is polished. Thereafter, a resist is formed on the polished surface so as to be the concentric circle having the same center as that of the operating region 15. After Ti is formed by sputtering, the resist is peeled to form the light shielding film 16.

The diameter of the concentric circle formed on the rear surface of the substrate 11 does not necessarily coincide with the diameter of the operating region 15 of the semiconductor light receiving element 10, that is, the contact layer 14. When the incident light is parallel light, there is no problem even if the diameter of the concentric circle coincides with the diameter of the contact layer 14. When the incident light is diffused light or converged light, the beam diameter incident on the contact layer 14 is different from the beam diameter on the rear surface of the substrate 11. In this case, the diameter of the concentric circle may be appropriately determined at the substrate thickness and the focal position of the incident light. The light shielding film does not need to completely block light, and the transmittance of the region inside the concentric circle having the same center as the operating region 15 may be higher than the transmittance of the outside of the concentric circle.

As described above, by applying the structure of the first embodiment, optical alignment is performed in the rear surface incidence type light receiving element, and high-speed operation can be secured at the same time.

### Second Embodiment

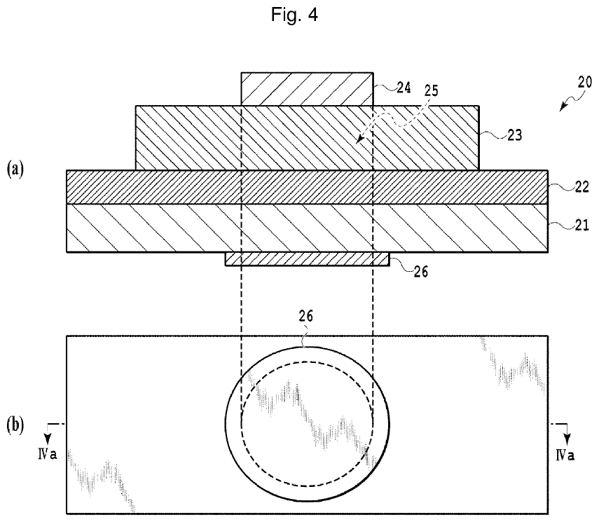

FIG. 4 shows a structure of a light receiving element according to a second embodiment of the present invention. FIG. 4 (a) is a cross-sectional view of the semiconductor light receiving element 20 of the vertical incidence type. The semiconductor light receiving element 20 has a layer structure in which a p-type InP contact layer 22, an undoped InGaAs light absorbing layer 23, and an n-type InP contact layer 24 are laminated in this order on the front surface of an InP substrate 21. An uppermost contact layer 24 is processed into the smallest mesa, and has a multi-stage Mesa structure in which the outer shape of the light absorbing layer 23 and the contact layer 22 is gradually increased in this order. The mesa of the uppermost contact layer 24 is formed in a circular shape. FIG. 4 (b) is a bottom view of the semiconductor light receiving element 20. On the rear surface of the light receiving element 20, an anti-reflection film 26 made of a dielectric multilayer film made of SiO₂/TiO₂ is provided in a concentric circle shape having the same center as an operating region 25 defined by the contact layer 24.

The operation principle of the semiconductor light receiving element 20 according to the second embodiment of the present invention will be described. Incident light to the light receiving element 20 is made incident from the rear surface of the substrate 21. The incident light is absorbed by the light absorbing layer 23, a photo-carrier is generated, and a current flows between the contact layers 22 and 24, thereby functioning as the light receiving element.

Here, when incident light from the rear surface is incident on the center part of the operating region 25, the incident light is transmitted through the region where the anti-reflection film 26 is formed, so that reflection on the rear surface of the substrate 21 is suppressed, and reaches the light absorbing layer 23 at a transmittance close to 100%. Therefore, the photocurrent at the time of alignment indicates the maximum value. Since the incident light is made incident on the central part of the operating region 25, all the generated photocarriers are subjected to the effect of an electric field generated in the operating region 25 and drift-move. Therefore, a desired high speed operation can be realized.

On the other hand, when the incident light is deviated from the center part of the operating region 25, a part of the incident light is not transmitted through the anti-reflection film 26, reflected at the rear surface of the substrate 21, and the observed photocurrent is extremely reduced. In this way, the transmittance of the light inside the concentric circle having the same center as the operating region 25 is higher than that of the region outside the concentric circle. Therefore, the photocurrent is maximized only when the signal light enters the center part of the operating region 25. Thus, the accuracy of the alignment can be improved even in the case of the optical alignment by the non-modulated light (the CW light), and the high-speed operation can be realized even in the case of receiving the modulated light of several tens GHz.

Next, a manufacturing method of the semiconductor light receiving element 20 of the second embodiment will be described. First, the p-type InP contact layer 22, the undoped InGaAs light absorbing layer 23, and the n-type InP light absorbing layer 24 are epitaxially grown in this order on the front surface of the semi-insulating InP substrate 21 by MOCVD. After crystal growth, photo lithography and etching are sequentially performed so that the contact layer 24 becomes the smallest mesa, and the light absorbing layer 23 and the contact layer 22 become larger in area in this order. After a necessary electrode or the like is formed on the contact layers 22 and 24, the rear surface of the light receiving element 20, that is, the rear surface of the substrate 21 is polished. Thereafter, the anti-reflection film of SiO₂/TiO₂ is formed on the polished surface by sputtering. A resist is formed so as to be the concentric circle having the same center as that of the operating region 25, the anti-reflection film 26 is processed into a circular shape by dry etching, and the resist is peeled.

The diameter of the concentric circle formed on the rear surface of the substrate 21 does not necessarily coincide with the diameter of the operating region 25 of the semiconductor light receiving element 20, that is, the contact layer 24. When the incident light is parallel light, there is no problem even if the diameter of the concentric circle coincides with the diameter of the contact layer 24. When the incident light is diffused light or converged light, the beam diameter incident on the contact layer 24 is different from the beam diameter on the rear surface of the substrate 21. In this case, the diameter of the concentric circle may be appropriately determined at the substrate thickness and the focal position of the incident light. The anti-reflection film does not need to completely reflect light, and the transmittance of the region inside the concentric circle whose center is the same as that of the operating region 25 is higher than the transmittance of the outside of the concentric circle.

As described above, by applying the structure of the first embodiment, optical alignment is performed in the rear surface incidence type light receiving element, and high-speed operation can be secured at the same time.

### Third Embodiment

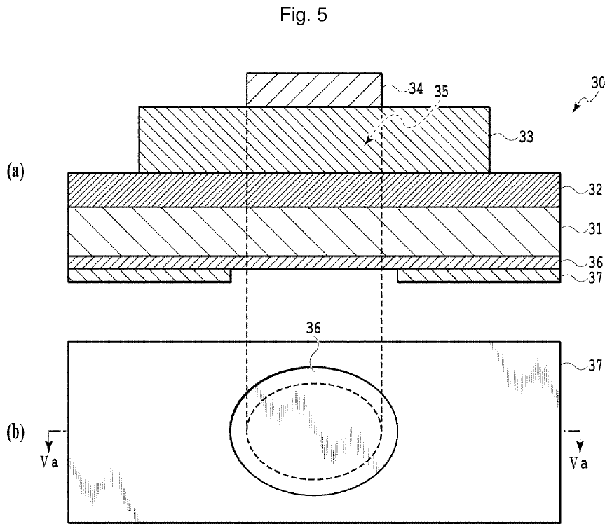

FIG. 5 shows a structure of a light receiving element according to a third embodiment of the present invention. FIG. 5 (a) is a cross-sectional view of a semiconductor light receiving element 30 of the vertical incidence type. The semiconductor light receiving element 30 has a layer structure in which a p-type InP contact layer 32, an undoped InGaAs light absorbing layer 33, and an n-type InP contact layer 34 are laminated in this order on the front surface of an InP substrate 31. An uppermost contact layer 34 is processed into the smallest mesa, and has a multi-stage mesa structure in which the outer shape of the light absorbing layer 33 and the contact layer 32 is gradually increased in this order. The mesa of the uppermost contact layer 34 is formed in an elliptical shape. FIG. 5 (b) is a bottom view of the semiconductor light receiving element 30. An anti-reflection film 36 of SiO₂/TiO₂ is formed on the rear surface of the light receiving element 30, and a light shielding film 37 of Ti is provided on an outside of an ellipse having the same center as an operating region 35 defined by the contact layer 34. The anti-reflection film 36 is exposed on the inside of the ellipse.

The operation principle of the semiconductor light receiving element 30 according to the third embodiment of the present invention will be described. Incident light to the light receiving element 30 is made incident from the rear surface of the substrate 31. The incident light is absorbed by the light absorbing layer 33, a photo-carrier is generated, and a current flows between the contact layers 32 and 34, thereby functioning as the light receiving element.

Here, when incident light from the rear surface is incident on the center part of the operating region 35, the incident light is transmitted through the region where the anti-reflection film 36 is formed, so that reflection on the rear surface of the substrate 31 is suppressed, and reaches the light absorbing layer 33 at a transmittance close to 100%. Therefore, the photocurrent at the time of alignment indicates the maximum value. Since the incident light is made incident on the central part of the operating region 35, all the generated photocarriers are subjected to the effect of an electric field generated in the operating region 35 and drift-move. Therefore, a desired high speed operation can be realized.

On the other hand, when the incident light is deviated from the center of the operating region 35, a part of the incident light is shielded by the light shielding film 37, so that the observed photocurrent is extremely reduced. In this way, the transmittance of the light inside the elliptical shape having the same center as the operating region 35 is higher than that of the region outside the elliptical shape. Therefore, the photocurrent is maximized only when the signal light enters the central portion of the operating region 35. Thus, the accuracy of the alignment can be improved even in the case of the optical alignment by the non-modulated light beam, the CW light beam, and the high-speed operation can be realized even in the case of receiving the modulated light beam of several tens GHz.

Next, a manufacturing method of the semiconductor light source element 30 of the third embodiment will be described. First, the p-type InP contact layer 32, the undoped InGaAs light absorbing layer 33, and the n-type InP light absorbing layer 34 are epitaxially grown in this order on the front surface of the semi-insulating InP substrate 31 by MOCVD. After crystal growth, photo lithography and etching are sequentially performed so that the contact layer 34 becomes the smallest mesa, and the light absorbing layer 33 and the contact layer 32 become larger in area in this order. After a necessary electrode or the like is formed on the contact layers 32 and 34, the rear surface of the light receiving element 30, that is, the rear surface of the substrate 31 is polished. Thereafter, an anti-reflection film 36 of SiO₂/TiO₂ is formed on the polished surface by sputtering. After the anti-reflection film 36 is formed, a resist which becomes an ellipse having the same center as that of the operating region 35 is formed. After Ti is formed by sputtering, the resist is peeled to form the light shielding film 37.

The major and minor axes of the ellipse formed on the rear surface of the substrate 31 do not necessarily coincide with the major and minor axes of the operating region 35 of the semiconductor light receiving element 30, that is, the contact layer 34. When the incident light is parallel light, there is no problem even if the major and minor axes of the ellipse coincide with the major and minor axes of the contact layer 34. When the incident light is diffused light or converged light, the beam diameter incident on the contact layer 34 is different from the beam diameter on the rear surface of the substrate 31. In this case, the major and minor axes of the ellipse may be appropriately determined at the substrate thickness and the focal position of the incident light.

As described above, by applying the structure of the third embodiment, optical alignment is performed in the rear surface incidence type light receiving element, and high-speed operation can be secured at the same time.

### Fourth Embodiment

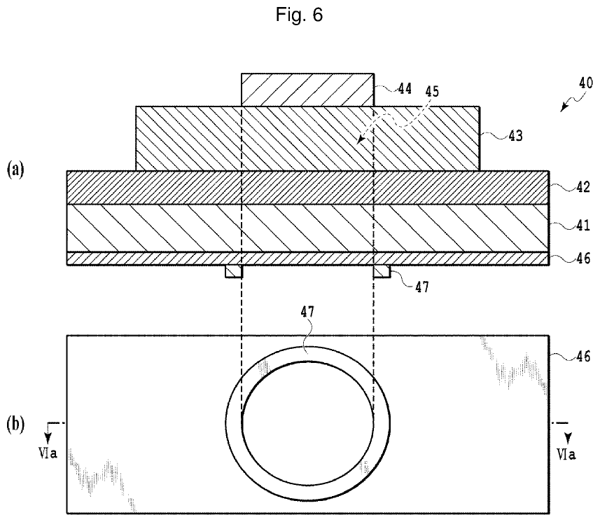

FIG. 6 shows a structure of a light receiving element according to a fourth embodiment of the present invention. FIG. 6 (a) is a cross-sectional view of a semiconductor light receiving element 40 of the vertical incidence type. The semiconductor light receiving element 40 has a layer structure in which a p-type InP contact layer 42, an undoped InGaAs light absorbing layer 43, and an n-type InP contact layer 44 are laminated in this order on the front surface of an InP substrate 41. An uppermost contact layer 44 is processed into the smallest mesa, and has a multi-stage mesa structure in which the outer shape of the light absorbing layer 43 and the contact layer 42 is gradually increased in this order. The mesa of the uppermost contact layer 44 is formed in a circular shape. FIG. 6 (b) is a bottom view of the semiconductor light receiving element 40. An anti-reflection film 46 of SiO₂/TiO₂ is formed on the rear surface of the light receiving element 40, and a ring-shaped light shielding film 47 of Ti is provided on a concentric circle having the same center as an operating region 35 defined by the contact layer 44. An anti-reflection film 36 is exposed on the rear surface except for the light shielding film 47.

The operation principle of the semiconductor light receiving element 40 according to the fourth embodiment of the present invention will be described. Incident light to the light receiving element 40 is made incident from the rear surface of the substrate 41. The incident light is absorbed by the light absorbing layer 43, a photo-carrier is generated, and a current flows between the contact layers 42 and 44, thereby functioning as the light receiving element.

Here, when incident light from the rear surface is incident on the center part of the operating region 45, the incident light is transmitted through the region where the anti-reflection film 46 is formed, so that reflection on the rear surface of the substrate 41 is suppressed, and reaches the light absorbing layer 43 at a transmittance close to 100%. Therefore, the photocurrent at the time of alignment indicates the maximum value. Since the incident light is made incident on the central part of the operating region 45, all the generated photocarriers are subjected to the effect of an electric field generated in the operating region 45 and drift-move. Therefore, a desired high speed operation can be realized.

On the other hand, when the incident light is deviated from the center of the operating region 45, a part of the incident light is shielded by the ring-shaped light shielding film 47, so that the observed photocurrent is extremely reduced. In this way, the transmittance of light inside the ring having the same center as the operating region 45 is higher than the transmittance of a region outside the ring. Therefore, the photocurrent is maximized only when the signal light enters the center part of the operating region 45. Thus, the accuracy of the alignment can be improved even in the case of the optical alignment by the non-modulated light (the CW light), and the high-speed operation can be realized even in the case of receiving the modulated light of several tens GHz.

Next, a manufacturing method of the semiconductor light receiving element 40 of the fourth embodiment will be described. First, the p-type InP contact layer 42, the undoped InGaAs light absorbing layer 43, and the n-type InP light absorbing layer 44 are epitaxially grown in this order on the front surface of the semi-insulating InP substrate 41 by MOCVD. After crystal growth, photo lithography and etching are sequentially performed so that the contact layer 44 becomes the smallest mesa, and the light absorbing layer 43 and the contact layer 42 become larger in area in this order. After a necessary electrode or the like is formed on the contact layers 42 and 44, the rear surface of the light receiving element 40, that is, the rear surface of the substrate 41 is polished. Thereafter, an anti-reflection film 46 of SiO₂/TiO₂ is formed on the polished surface by sputtering. After the anti-reflection film 46 is formed, a resist having a concentric ring shape with the same center as that of the operating region 45 is formed. After Ti is formed by sputtering, the resist is peeled to form the light shielding film 47.

The diameter of the concentric ring formed on the rear surface of the substrate 41 does not necessarily coincide with the diameter of the operating region 45 of the semiconductor light receiving element 40, that is, the diameter of the contact layer 44. When the incident light is parallel light, there is no problem even if the diameter of the concentric circle coincides with the diameter of the contact layer 44. When the incident light is diffused light or converged light, the beam diameter incident on the contact layer 44 is different from the beam diameter on the rear surface of the substrate 41. In this case, the diameter of the concentric circle may be appropriately determined at the substrate thickness and the focal position of the incident light.

As described above, by applying the structure of the fourth embodiment, optical alignment is performed in the rear surface incidence type light receiving element, and high-speed operation can be secured at the same time.

### Other Embodiments

Although the first to the fourth embodiment have been described with reference to the InGaAs light receiving element, it is apparent that the present invention can be applied to light receiving elements of other material bases such as Si and SiGe base. Further, a mirror may be formed on the light absorbing layer side of the light receiving element, that is, on the mesa side of the contact layer, and a so-called “two path structure” in which the incident light is reflected on the surface side may be adopted.

The thickness of the substrate and the thickness of the mesa are not limited in addition to the diameter of the concentric circle, the major and the minor diameters of the ellipse. Further, the shape of the operating region defined by the contact layer is not limited to the circular shape or the elliptical shape, and any shape may be used. The shape having the same center as that of the operating region formed on the rear surface may be similar to that of the operating region, and it should be suitably designed in an optical system for making the signal light incident on the light receiving element.

Further, although all the light receiving elements having the mesa structure have been exemplified in the present embodiments, it is needless to say that the present invention can be applied to the light receiving element having a so-called “planar structure” using ion implantation structure and selective diffusion. These embodiments are vertical incidence type, and are widely effective technique as long as they have some electric field constriction structure.

Alignment marks can be formed simultaneously in the rear surface process in the method of manufacturing the light receiving element. For example, rough alignment can be performed by passive alignment by an alignment mark, and highly accurate alignment can be performed by active alignment.

1. A semiconductor light-receiving element, including a semiconductor light absorbing layer on a front surface of a semiconductor substrate, for receiving a signal light from a rear surface of the semiconductor substrate,
wherein a transmittance of an inner region on the rear surface of the semiconductor substrate with a similar shape having a same center as an operating region defined in the semiconductor light absorbing layer is higher than a transmittance of an outside of the inner region.

2. The semiconductor light-receiving element according to claim 1, wherein
a light shielding film is formed on the outside of the inner region.

3. The semiconductor light-receiving element according to claim 1, wherein
an anti-reflection film with the similar shape having the same center as the operating region is formed.

4. The semiconductor light-receiving element according to claim 1, wherein
an anti-reflection film is formed on the rear surface of the semiconductor substrate, and
a ring-shaped light-shielding film is formed on a concentric circle having the same center as the operating region on the outside of the inner region.

5. The semiconductor light-receiving element according to claim 3, wherein
the anti-reflection film is formed of a dielectric multilayer film.

6. The semiconductor light-receiving element according to claim 1, wherein
the similar shape having the same center as that of the operating region is a circular shape or an elliptical shape.
